(19) United States
(12) Patent Application Publication
(10) Pub. No.: US 2009/0269683 A1
(43) Pub. Date: Oct. 29, 2009

(54) RADIATION-SENSITIVE RESIN COMPOSITION AND COLOR FILTERS

(75) Inventors: Tatsuyoshi Kawamoto, Tokyo (JP); Tsukasa Toyoshima, Tokyo (JP); Masashi Arai, Tokyo (JP); Ryu Matsumoto, Tokyo (JP); Tomio Nagatsuka, Tokyo (JP); Toshihiro Tadaki, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: JSR CORPORATION, CHUO-KU (JP)

(21) Appl. No.: 12/066,304

(22) PCT Filed: Sep. 7, 2006
(86) PCT No.: PCT/JP2006/318206

§ 371 Date: Mar. 10, 2008

(30) Foreign Application Priority Data
Sep. 8, 2005 (JP) 2005-260503
Sep. 9, 2005 (JP) 2005-262910

(51) Int. Cl. G03F 1/00; G03F 7/004

(52) U.S. Cl. 430/7; 430/270.1; 430/286.1

(57) ABSTRACT

A radiation sensitive resin composition comprising (A) a colorant, (B) an alkali-soluble resin, (C) a polyfunctional monomer and (D) a radiation sensitive radical generator, wherein
the alkali-soluble resin (B) is a resin having a group containing a dithiocarbonyl bond at least one terminal of its polymer chain.

A color filter which is free from burning can be manufactured from this composition at a high yield.

### TECHNICAL FIELD

The present invention relates to a radiation sensitive resin composition useful for the manufacture of a color filter for use in transmission and reflection type color liquid crystal devices and color image pick-up devices, a method of manufacturing the same, a color filter formed from the radiation sensitive resin composition, and a color liquid crystal display device comprising the color filter.

### BACKGROUND ART

As means of forming a color filter from a colored radiation sensitive resin composition, there is known a method in which a coating film of a colored radiation sensitive resin composition is formed on a substrate or a substrate comprising a light screening layer having a desired pattern, exposed to radiation (to be referred to as “exposure” hereinafter) through a photomask having a desired pattern shape, developed with an alkali developer to dissolve and remove an unexposed portion and post-baked in a clean oven or on a hot plate so as to obtain color pixels (refer to JP-A 2000-329929).

Since substrates used to form color filters are becoming larger in size, means of applying the radiation sensitive resin composition is shifting from spin coating by dropping the composition on the center of a substrate to slit nozzle coating using a small-diameter liquid ejection portion for applying the radiation sensitive resin composition. In the latter slit nozzle coating, as the diameter of the liquid ejection portion is small (narrow), the radiation sensitive resin composition often remains around the end of the nozzle after coating. When the resin composition becomes dry, it falls on a color filter as dry foreign matter at the time of next coating and greatly reduces the quality of the color filter. Therefore, a jet of a cleaning solvent is generally applied to the end of the nozzle before coating to clean it. However, the deterioration of the color filter by the dry foreign matter still cannot be prevented effectively, thereby causing a reduction in product yield.

To cope with this problem, a radiation sensitive resin composition for color filters which has cleanability with a cleaning solvent, that is, high solubility in a cleaning solvent even after it becomes dry is now in demand.

Long service life is now required for a liquid crystal display device comprising a color filter, and the requirement for the “burning” preventing ability of the color filter is becoming stronger.

The term “burning” is a kind of display failure of a liquid crystal display device and a phenomenon that an image which should not be displayed is displayed on the screen, or a black or white “fog” is displayed over an image which should be displayed. The cause of this phenomenon is considered as follows. That is, charged impurities contained in liquid crystals spread into the liquid crystals, thereby making it impossible to maintain a potential difference applied to align the liquid crystal molecules for a certain period of time. It has recently been found that the impurities are produced not only at the time of manufacturing the liquid crystal molecules but also from the inside of the formed color filter. As disclosed by JP-A 2000-329929, it is known that increasing the purity of a pigment is effective in preventing the “burning”. However, as the impurities may be derived from components other than the pigment contained in the radiation sensitive resin composition, it cannot be said that increasing the purity of the pigment can always prevent the above phenomenon completely.

Then, the development of a further improved radiation sensitive resin composition for color filters which meets the requirement for high product yield and is free from “burning” at the time of manufacturing a color filter is strongly desired.

### DISCLOSURE OF THE INVENTION

It is an object of the present invention to provide a radiation sensitive resin composition which can provide a color filter free from “burning” at a high product yield and has high solubility in a solvent even after it becomes dry.

It is another object of the present invention to provide a method of preparing the above radiation sensitive resin composition of the present invention.

It is still another object of the present invention to provide a color filter.

It is a further object of the present invention to provide a color liquid crystal display device comprising the above color filter.

Other objects and advantages of the present invention will become apparent from the following description.

According to the present invention, firstly, the above objects and advantages of the present invention are attained by a radiation sensitive resin composition comprising (A) a colorant, (B) an alkali-soluble resin, (C) a polyfunctional monomer and (D) a radiation sensitive radical generator, wherein

the alkali-soluble resin (B) is a resin having a group represented by the following formula (i) or (ii) at least one terminal of its polymer chain.

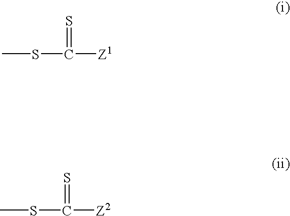

[Z¹ in the formula (i) and Z² in the formula (ii) are each independently a hydrogen atom, chlorine atom, carboxyl group, cyano group, alkyl group having 1 to 20 carbon atoms, monovalent aromatic hydrocarbon group having 6 to 20 carbon atoms, monovalent heterocyclic group having 3 to 20 atoms consisting of carbon atoms and other atoms, —OR¹, —SR¹, —OC(═O)R¹, —N(R¹)(R²), —C(═O)OR¹, —C(═O)N(R¹)(R²), —P(═O) (OR¹)₂, —P(═O) (R¹)₂ (R¹ and R² are each independently an alkyl group having 1 to 18 carbon atoms, alkenyl group having 2 to 18 carbon atoms, monovalent aromatic hydrocarbon group having 6 to 18 carbon atoms or monovalent heterocyclic group having 3 to 18 atoms consisting of carbon atoms and other atoms) or monovalent group having a polymer chain, with the proviso that the alkyl group having 1 to 20 carbon atoms, the monovalent aromatic hydrocarbon group having 6 to 20 carbon atoms, the monovalent heterocyclic group having 3 to 20 atoms consisting of carbon atoms and other atoms, R¹ and R² may be substituted.]

According to the present invention, secondly, the above objects and advantages of the present invention are attained by a method of preparing the above radiation sensitive resin composition, comprising mixing a pigment dispersion obtained by mixing and dispersing a pigment as (A) a colorant in a solvent while it is ground in the presence of a dispersant with (B) an alkali-soluble resin, (C) a polyfunctional monomer and (D) a radiation sensitive radical generator.

According to the present invention, thirdly, the above objects and advantages of the present invention are attained by the above radiation sensitive resin composition which is used for color filters (to be referred to as “radiation sensitive resin composition for color filters” hereinafter).

According to the present invention, in the fourth place, the above objects and advantages of the present invention are attained by a color filter formed from the radiation sensitive resin composition for color filters.

According to the present invention, in the fifth place, the above objects and advantages of the present invention are attained by a color liquid crystal display device comprising the above color filter.

### BEST MODE FOR CARRYING OUT THE INVENTION

The present invention will be described in detail hereinunder.

### Radiation Sensitive Resin Composition

### —(A) Colorant—

The colorant in the present invention is not particularly limited but preferably a pigment, particularly preferably an organic pigment or carbon black as the development of a high-purity and high-transmission color or shielding properties and heat resistance are required for color filters.

Examples of the above organic pigment are compounds classified into a group of pigments according to color index, specifically compounds having the following color index (C.I.) numbers:

C.I. Pigment Yellow 12, C.I. Pigment Yellow 13, C.I. Pigment Yellow 14, C.I. Pigment Yellow 17, C.I. Pigment Yellow 20, C.I. Pigment Yellow 24, C.I. Pigment Yellow 31, C.I. Pigment Yellow 55, C.I. Pigment Yellow 83, C.I. Pigment Yellow 93, C.I. Pigment Yellow 109, C.I. Pigment Yellow 110, C.I. Pigment Yellow 138, C.I. Pigment Yellow 139, C.I. Pigment Yellow 150, C.I. Pigment Yellow 153, C.I. Pigment Yellow 154, C.I. Pigment Yellow 155, C.I. Pigment Yellow 166, C.I. Pigment Yellow 168 and C.I. Pigment Yellow 211;
C.I. Pigment Orange 5, C.I. Pigment Orange 13, C.I. Pigment Orange 14, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 61, C.I. Pigment Orange 64, C.I. Pigment Orange 68, C.I. Pigment Orange 70, C.I. Pigment Orange 71, C.I. Pigment Orange 72, C.I. Pigment Orange 73 and C.I. Pigment Orange 74;
C.I. Pigment Red 1, C.I. Pigment Red 2, C.I. Pigment Red 5, C.I. Pigment Red 17, C.I. Pigment Red 31, C.I. Pigment Red 32, C.I. Pigment Red 41, C.I. Pigment Red 122, C.I. Pigment Red 123, C.I. Pigment Red 144, C.I. Pigment Red 149, C.I. Pigment Red 166, C.I. Pigment Red 168, C.I. Pigment Red 170, C.I. Pigment Red 171, C.I. Pigment Red 175, C.I. Pigment Red 176, C.I. Pigment Red 177, C.I. Pigment Red 178, C.I. Pigment Red 179, C.I. Pigment Red 180, C.I. Pigment Red 185, C.I. Pigment Red 187, C.I. Pigment Red 202, C.I. Pigment Red 206, C.I. Pigment Red 207, C.I. Pigment Red 209, C.I. Pigment Red 214, C.I. Pigment Red 220, C.I. Pigment Red 221, C.I. Pigment Red 224, C.I. Pigment Red 242, C.I. Pigment Red 243, C.I. Pigment Red 254, C.I. Pigment Red 255, C.I. Pigment Red 262, C.I. Pigment Red 264 and C.I. Pigment Red 272;

### C.I. Pigment Violet 1, C.I. Pigment Violet 19, C.I. Pigment Violet 23, C.I. Pigment Violet 29, C.I. Pigment Violet 32, C.I. Pigment Violet 36 and C.I. Pigment Violet 38;

### C.I. Pigment Blue 15, C.I. Pigment Blue 15:3, C.I. Pigment Blue 15:4, C.I. Pigment Blue 15:6, C.I. Pigment Blue 60 and C.I. Pigment Blue 80;

### C.I. Pigment Green 7 and C.I. Pigment Green 36;

### C.I. Pigment Brown 23 and C.I. Pigment Brown 25; and

### C.I. Pigment Black 1 and C.I. Pigment Black 7.

Out of these organic pigments, C.I. Pigment Yellow 83, C.I. Pigment Yellow 139, C.I. Pigment Yellow 138, C.I. Pigment Yellow 150, C.I. Pigment Yellow 180, C.I. Pigment Red 177, C.I. Pigment Red 254, C.I. Pigment Blue 15:3, C.I. Pigment Blue 15:4, C.I. Pigment Blue 15:6, C.I. Pigment Green 7, C.I. Pigment Green 36, C.I. Pigment Violet 23, C.I. Pigment Blue 60 and C.I. Pigment Blue 80 are preferred.

The above organic pigments may be used alone or in combination of two or more, and a mixture of an organic pigment and carbon black may also be used.

In the present invention, when a pigment is used as the colorant of the radiation sensitive resin composition, the radiation sensitive resin composition is preferably prepared by mixing and dispersing the pigment in a solvent while it is ground by a bead mill or a roll mill in the presence of a dispersant to prepare a pigment dispersion and mixing the pigment dispersion with the components (B), (C) and (D) which will be described hereinafter and optionally with an additional solvent and other additives which will be described hereinafter.

The dispersant used to prepare the above pigment dispersion may be a cationic, anionic, nonionic or ampholytic dispersant. A dispersant containing a compound having an urethane bond (to be referred to as “urethane-based dispersant” hereinafter) is preferred.

The above urethane bond is generally represented by the formula R—NH—COO—R′ (R and R′ are each independently an aliphatic, alicyclic or aromatic monovalent or polyvalent organic group, and the polyvalent organic group is further bonded to a group having another urethane bond or another group). The urethane bond may exist in a lipophilic group and/or a hydrophilic group contained in the urethane-based dispersant or the main chain and/or side chain of the urethane-based dispersant. One or more urethane bonds may exist in the urethane-based dispersant. When two or more urethane bonds are existent in the urethane-based dispersant, they may be the same or different.

The urethane-based dispersant is, for example, a reaction product of a diisocyanate and/or a triisocyanate and a polyester having a hydroxyl group at one terminal and/or a polyester having a hydroxyl group at both terminals.

Examples of the above diisocyanate include benzene diisocyanates such as benzene-1,3-diisocyanate and benzene-1,4-diisocyanate; toluene diisocyanates such as toluene-2,4-diisocyanate, toluene-2,5-diisocyanate, toluene-2,6-diisocyanate and toluene-3,5-diisocyanate; and other aromatic diisocyanates such as xylene diisocyanates including 1,2-xylene-3,5-diisocyanate, 1,2-xylene-3,6-diisocyanate, 1,3-xylene-2,4-diisocyanate, 1,3-xylene-2,5-diisocyanate, 1,3-xylene-4,6-diisocyanate, 1,4-xylene-2,5-diisocyanate and 1,4-xylene-2,6-diisocyanate.

Examples of the above triisocyanate include benzene triisocyanates such as benzene-1,2,4-triisocyanate, benzene-1,2,5-triisocyanate and benzene-1,3,5-triisocyanate; toluene triisocyanates such as toluene-2,3,5-triisocyanate, toluene-2,3,6-triisocyanate, toluene-2,4,5-triisocyanate and toluene-2,4,6-triisocyanate; and other aromatic triisocyanates such as xylene triisocyanates including 1,2-xylene-3,4,5-triisocyanate, 1,2-xylene-3,4,6-triisocyanate, 1,3-xylene-2,4,5-triisocyanate, 1,3-xylene-2,4,6-triisocyanate, 1,3-xylene-4,5,6-triisocyanate, 1,4-xylene-2,3,5-triisocyanate and 1,4-xylene-2,3,6-triisocyanate.

These diisocyanates and triisocyanates may be used alone or in combination of two or more.

Examples of the polyester having a hydroxyl group at one terminal and the polyester having a hydroxyl group at both terminals include polylactones having a hydroxyl group at one terminal or both terminals such as polycaprolactone having a hydroxyl group at one terminal or both terminals, polyvalerolactone having a hydroxyl group at one terminal or both terminals and polypropiolactone having a hydroxyl group at one terminal or both terminals; and polycondensation polyesters having a hydroxyl group at one terminal or both terminals such as polyethylene terephthalate having a hydroxyl group at one terminal or both terminals and polybutylene terephthalate having a hydroxyl group at one terminal or both terminals.

These polyesters having a hydroxyl group at one terminal and these polyesters having a hydroxyl group at both terminals may be used alone or in combination of two or more.

The urethane-based dispersant in the present invention is preferably a reaction product of an aromatic diisocyanate and a polylactone having a hydroxyl group at one terminal and/or a polylactone having a hydroxyl group at both terminals, particularly preferably a reaction product of a toluene diisocyanate and polycaprolactone having a hydroxyl group at one terminal and/or polycaprolactone having a hydroxyl group at both terminals.

Examples of the urethane-based dispersant include Disperbyk161 and Disperbyk170 (of BYK Co., Ltd.), EFKA (of EFKA Chemicals BV) and Disparon (of Kusumoto Kasei Co., Ltd.).

Mw of the urethane-based dispersant in the present invention is preferably 5,000 to 50,000, more preferably 7,000 to 20,000.

The above urethane-based dispersants may be used alone or in combination of two or more.

A (meth)acrylic dispersant composed of a (co)polymer of a (meth)acrylic monomer is also preferred as the dispersant.

Examples of the (meth)acrylic dispersant include Disperbyk2000 and Disperbyk2001 (of BYK Co., Ltd.).

The above (meth) acrylic dispersants may be used alone or in combination of two or more.

The amount of the dispersant used to prepare a dispersion of a colorant such as a pigment or carbon black is preferably 100 parts or less by weight, more preferably 0.5 to 100 parts by weight, much more preferably 1 to 70 parts by weight, particularly preferably 10 to 50 parts by weight based on 100 parts by weight of the pigment. When the amount of the dispersant is larger than 100 parts by weight, developability may be impaired.

The solvent used to prepare the pigment dispersion may be identical to a solvent used to prepare a liquid radiation sensitive resin composition which will be described hereinafter.

The amount of the solvent used to prepare the pigment dispersion is preferably 500 to 1,000 parts by weight, more preferably 700 to 900 parts by weight based on 100 parts by weight of the pigment.

To prepare the pigment dispersion by using a bead mill, glass beads or titania beads having a diameter of about 0.5 to 10 mm are used to mix and disperse a pigment mixed solution comprising a pigment, a solvent and a dispersant preferably while it is cooled with cooling water or the like.

In this case, the filling rate of the beads is preferably 50 to 80% of the capacity of the mill, and the amount of the pigment mixed solution injected is preferably about 20 to 50% of the capacity of the mill. The treating time is preferably 2 to 50 hours, more preferably 2 to 25 hours.

To prepare the pigment dispersion by using a roll mill, a three-roll mill or a two-roll mill is used to mix and disperse the pigment mixed solution preferably while it is cooled with cooling water or the like.

In this case, the interval between rolls is preferably 10 μm or less, and the shearing force is preferably about 10⁸ dyn/sec. The treating time is preferably 2 to 50 hours, more preferably 2 to 25 hours.

### —(B) Alkali-Soluble Resin—

The alkali-soluble resin in the present invention is a resin having a group represented by the above formula (i) or (ii) at least one terminal of its polymer chain (to be referred to as “resin (B)” hereinafter).

In the formulas (i) and (ii), examples of the alkyl group having 1 to 20 carbon atoms represented by Z¹ and Z² include methyl group, ethyl group, n-propyl group, i-propyl group, n-butyl group, i-butyl group, sec-butyl group, t-butyl group, n-pentyl group, n-hexyl group, n-heptyl group, n-octyl group, n-nonyl group, n-decyl group, n-dodecyl group, n-tetradecyl group, n-hexadecyl group, n-octadecyl group and n-eicosyl group.

Examples of the monovalent aromatic hydrocarbon group having 6 to 20 carbon atoms represented by Z¹ and Z² include phenyl group, 1-naphthyl group, 2-naphthyl group, 1-anthracenyl group, 9-anthracenyl group, benzyl group and phenethyl group.

Examples of the monovalent heterocyclic group having 3 to 20 atoms consisting of carbon atoms and other atoms represented by Z¹ and Z² include oxiranyl group, aziridinyl group, 2-furanyl group, 3-furanyl group, 2-tetrahydrofuranyl group, 3-tetrahydrofuranyl group, 1-pyrrole group, 2-pyrrole group, 3-pyrrole group, 1-pyrrolidinyl group, 2-pyrrolidinyl group, 3-pyrrolidinyl group, 1-pyrazole group, 2-tetrahydropyranyl group, 3-tetrahydropyranyl group, 4-tetrahydropyranyl group, 2-thianyl group, 3-thianyl group, 4-thianyl group, 2-pyridinyl group, 3-pyridinyl group, 4-pyridinyl group, 2-piperidinyl group, 3-piperidinyl group, 4-piperidinyl group, 2-morpholinyl group and 3-morpholinyl group.

Examples of the alkyl group having 1 to 18 carbon atoms, the monovalent aromatic hydrocarbon group having 6 to 18 carbon atoms and the monovalent heterocyclic group having 3 to 18 atoms consisting of carbon atoms and other atoms represented by R¹ and R² in —OR¹, —SR¹, —C(═O)OR¹, —N(R¹)(R²)—OC(═O)R¹, —C(═O)N(R¹)(R²), —P(═O)(OR¹)₂ or —P(═O)(R¹)₂ represented by Z¹ and Z² are groups having 18 or less carbon atoms out of the alkyl groups having 1 to 20 carbon atoms, the monovalent aromatic hydrocarbon groups having 6 to 20 carbon atoms and the monovalent heterocyclic groups having 3 to 20 atoms consisting of carbon atoms and other atoms enumerated for Z¹ and Z², respectively.

Examples of the alkenyl group having 2 to 18 carbon atoms represented by R¹ and R² include vinyl group, 1-propenyl group, 2-propenyl group, 1-butenyl group, 2-butenyl group, 3-butenyl group, 1-pentenyl group, 2-pentenyl group, 3-pentenyl group, 4-pentenyl group, 1-hexenyl group, 2-hexenyl group, 3-hexenyl group, 4-hexenyl group and 5-hexenyl group.

The substituents for the alkyl group having 1 to 20 carbon atoms, the monovalent aromatic hydrocarbon group having 6 to 20 carbon atoms, the monovalent heterocyclic group having 3 to 20 atoms consisting of carbon atoms and other atoms, R¹ and R² can be suitably selected from chlorine atom; carboxyl group; cyano group; alkyl groups having 1 to 18 carbon atoms (excluding alkyl groups having 1 to 20 carbon atoms), monovalent aromatic hydrocarbon groups having 6 to 18 carbon atoms (excluding monovalent aromatic hydrocarbon groups having 6 to 20 carbon atoms) and monovalent heterocyclic groups having 3 to 18 atoms consisting of carbon atoms and other atoms (excluding monovalent heterocyclic groups having 3 to 20 atoms consisting of carbon atoms and other atoms) and alkenyl groups having 2 to 18 carbon atoms enumerated for R¹ and R²; and —OR¹, —SR¹, —OC(═O)R¹, —N(R¹)(R²), —C(═O)OR¹, —C(═O)N(R¹)(R²), —P(═O)(OR¹)₂ and —P(═O)(R¹)₂ enumerated for Z¹ and Z². One or more of the substituents of the same kind or different kinds may be existent in a substituted group. It is preferred that the total number of carbon atoms or the total number of atoms in the case of the heterocyclic group in the substituted group should not be larger than 20.

Examples of the monovalent group having a polymer chain represented by Z¹ and Z² include monovalent groups having an addition polymerization polymer chain formed from at least one unsaturated compound selected from an α-olefin such as ethylene or propylene; aromatic vinyl compound such as styrene or α-methylstyrene; vinyl halide such as vinyl fluoride, vinyl chloride or vinylidene chloride; unsaturated alcohol such as vinyl alcohol or allyl alcohol; ester of an unsaturated alcohol such as vinyl acetate or allyl acetate; unsaturated carboxylic acid such as (meth)acrylic acid or p-vinylbenzoic acid; (meth)acrylate such as methyl (meth)acrylate, ethyl(meth)acrylate, n-propyl(meth)acrylate, i-propyl(meth)acrylate, n-butyl(meth)acrylate, t-butyl (meth)acrylate, n-hexyl(meth)acrylate or cyclohexyl(meth)acrylate; (meth)acrylamide such as (meth)acrylamide or N,N-dimethyl(meth)acrylamide; unsaturated nitrile such as (meth)acrylonitrile or vinylidene cyanide; or conjugated diene such as butadiene or isoprene, and monovalent groups having a polyaddition polymer chain or polycondensation polymer chain, such as polyethers, polyesters, polyamides and polyimides. Z¹ in the formula (i) and Z² in the formula (2) are each preferably an alkyl group having 1 to 20 carbon atoms, a monovalent heterocyclic group having 3 to 20 atoms consisting of carbon atoms and other atoms, —OR¹ or —N(R¹)(R²), particularly preferably methyl group, ethyl group, 1-pyrrole group, 1-pyrazole group, methoxy group, ethoxy group, dimethylamino group or diethylamino group.

The resin (B) is not particularly limited if it serves as a binder for the colorant (A) and has solubility in a developer, preferably an alkali developer used in the development step of the color filter manufacturing process. Examples of the resin (B) include addition polymerization, polyaddition and polycondensation resins having an acid functional group (for example, carboxyl group, carboxyl anhydride group, phenolic hydroxyl group etc.) and/or an alcoholic hydroxyl group (these acid functional groups and these alcoholic hydroxyl groups are referred to as “alkali-soluble functional groups” hereinafter).

In the present invention, the preferred resin (B) is, for example, a resin having an alkali-soluble functional group which is manufactured through the polymerization of polymerizable unsaturated compounds. More specifically, it is a resin (to be referred to as “resin (B1)” hereinafter) having an alkali-soluble functional group which is manufactured through the polymerization of polymerizable unsaturated compounds using (1) a disulfide compound represented by the following formula (1) (to be referred to as “disulfide compound (I)” hereinafter) as a molecular weight control agent.

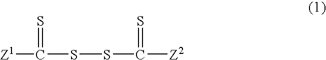

[In the formula (1), Z¹ and Z² are defined the same as Z¹ in the formula (i) and Z² in the formula (ii), respectively.]

Preferred examples of the disulfide compound (I) include tetraethylthiuram disulfide, bis(pyrazol-1-yl thiocarbonyl)disulfide, bis(3-methyl-pyrazol-1-yl thiocarbonyl)disulfide, bis(4-methyl-pyrazol-1-yl thiocarbonyl)disulfide, bis(5-methyl-pyrazol-1-yl thiocarbonyl)disulfide, bis(3,4,5-trimethyl-pyrazol-1-yl thiocarbonyl)disulfide, bis(pyrrol-1-yl thiocarbonyl)disulfide and bisthiobenzoyl disulfide.

In the present invention, the preferred resin (B1) is, for example, a copolymer (to be referred to as “alkali-soluble copolymer” hereinafter) of a polymerizable unsaturated compound having an alkali-soluble functional group and another copolymerizable unsaturated compound.

The particularly preferred alkali-soluble copolymer is, for example, a copolymer (to be referred to as “alkali-soluble copolymer (I)” hereinafter) of (b1) an unsaturated carboxylic acid and/or an unsaturated carboxylic anhydride (to be referred to as “unsaturated compound (b1)” hereinafter) and (b2) another copolymerizable unsaturated compound (to be referred to as “unsaturated compound (b2)” hereinafter).

Examples of the unsaturated compound (b1) include unsaturated monocarboxylic acids such as (meth) acrylic acid, crotonic acid, α-chloroacrylic acid and cinnamic acid; unsaturated dicarboxylic acids and anhydrides thereof such as maleic acid, maleic anhydride, fumaric acid, itaconic acid, itaconic anhydride, citraconic acid, citraconic anhydride and mesaconic acid; unsaturated polycarboxylic acids having three or more carboxyl groups and anhydrides thereof; mono[(meth)acryloyloxyalkyl]esters of a polycarboxylic acid having two or more carboxyl groups such as mono[2-(meth)acryloyloxyethyl]succinate and mono[2-(meth)acryloyloxyethyl]phthalate; and mono(meth)acrylates of a polymer having a carboxyl group and a hydroxyl group at both terminals such as ω-carboxypolycaprolactone mono(meth)acrylate.

Out of these unsaturated compounds (b1), (meth) acrylic acid, mono[2-(meth)acryloyloxyethyl]succinate and ω-carboxypolycaprolactone mono(meth)acrylate are particularly preferred.

The above unsaturated compounds (b1) may be used alone or in combination of two or more.

Examples of the unsaturated compound (b2) include aromatic vinyl compounds such as styrene, α-methylstyrene, o-hydroxystyrene, m-hydroxystyrene, p-hydroxystyrene, o-hydroxy-α-methylstyrene, m-hydroxy-α-methylstyrene, p-hydroxy-α-methylstyrene, p-styrenesulfonic acid, o-vinyltoluene, m-vinyltoluene, p-vinyltoluene, p-chlorostyrene, o-methoxystyrene, m-methoxystyrene, p-methoxystyrene, o-vinylbenzylmethyl ether, m-vinylbenzylmethyl ether, p-vinylbenzylmethyl ether, o-vinylbenzylglycidyl ether, m-vinylbenzylglycidyl ether and p-vinylbenzylglycidyl ether; indenes such as indene and 1-methylindene; N-(substituted)aryl maleimides such as N-phenylmaleimide, N-o-hydroxyphenylmaleimide, N-m-hydroxyphenylmaleimide, N-p-hydroxyphenylmaleimide, N-o-methylphenylmaleimide, N-m-methylphenylmaleimide, N-p-methylphenylmaleimide, N-o-methoxyphenylmaleimide, N-m-methoxyphenylmaleimide and N-p-methoxyphenylmaleimide, and N-substituted maleimides such as N-cyclohexylmaleimide; macromonomers having a (meth)acryloyl group at one terminal of a polymer molecular chain (to be simply referred to as “macromonomer” hereinafter) such as polystyrene, polymethyl (meth)acrylate, poly-n-butyl(meth)acrylate and polysiloxane; unsaturated carboxylates such as methyl(meth)acrylate, ethyl(meth)acrylate, n-propyl(meth)acrylate, i-propyl(meth)acrylate, n-butyl(meth)acrylate, i-butyl(meth)acrylate, sec-butyl(meth)acrylate, t-butyl(meth)acrylate, 2-hydroxyethyl(meth)acrylate, 2-hydroxypropyl(meth)acrylate, 3-hydroxypropyl(meth)acrylate, 2-hydroxybutyl(meth)acrylate, 3-hydroxybutyl(meth)acrylate, 4-hydroxybutyl(meth)acrylate, allyl(meth)acrylate, benzyl(meth)acrylate, cyclohexyl(meth)acrylate, phenyl(meth)acrylate, 2-methoxyethyl(meth)acrylate, 2-phenoxyethyl(meth)acrylate, methoxydiethylene glycol(meth)acrylate, methoxytriethylene glycol(meth)acrylate, methoxypropylene glycol(meth)acrylate, methoxydipropylene glycol(meth)acrylate, isobornyl(meth)acrylate, tricyclo[5.2.1.0^{2.6}]decan-8-yl(meth)acrylate, 2-hydroxy-3-phenoxypropyl(meth)acrylate and glycerol(meth)acrylate; unsaturated aminoalkyl carboxylates such as 2-aminoethyl(meth)acrylate, 2-dimethylaminoethyl(meth)acrylate, 2-aminopropyl(meth)acrylate, 2-dimethylaminopropyl(meth)acrylate, 3-aminopropyl (meth)acrylate and 3-dimethylaminopropyl(meth)acrylate; unsaturated glycidyl carboxylates such as glycidyl (meth)acrylate; vinyl carboxylates such as vinyl acetate, vinyl propionate, vinyl butyrate and vinyl benzoate; unsaturated ethers such as vinyl methyl ether, vinyl ethyl ether and allyl glycidyl ether; vinyl cyanide compounds such as (meth)acrylonitrile, α-chloroacrylonitrile and vinylidene cyanide; unsaturated amides such as (meth)acrylamide, α-chloroacrylamide and N-2-hydroxyethyl (meth)acrylamide; and aliphatic conjugated dienes such as 1,3-butadiene, isoprene, chloroprene and isoprenesulfonic acid.

Out of these unsaturated compounds (b2), styrene, macromonomers, N-substituted maleimides, methyl(meth)acrylate, 2-hydroxyethyl(meth)acrylate, allyl(meth)acrylate, benzyl(meth)acrylate, phenyl(meth)acrylate and glycerol mono(meth)acrylate are particularly preferred. Out of the macromonomers, polystyrene macromonomer and polymethyl(meth)acrylate macromonomer are particularly preferred, and out of the N-substituted maleimides, N-phenylmaleimide and N-cyclohexylmaleimide are particularly preferred.

The above unsaturated compounds (b2) may be used alone or in combination of two or more.

In the present invention, the preferred alkali-soluble copolymer (I) is, for example, a copolymer (to be referred to as “carboxyl group-containing copolymer (1-1)” hereinafter) of a monomer mixture of (b1) at least one unsaturated compound selected from the group consisting of (meth)acrylic acid, mono[2-(meth)acryloyloxyethyl]succinate and ω-carboxypolycaprolactone mono(meth)acrylate and (b2) at least one unsaturated compound selected from the group consisting of polystyrene macromonomer, polymethyl(meth)acrylate macromonomer, N-phenylmaleimide, N-cyclohexylmaleimide, 2-hydroxyethyl(meth)acrylate, benzyl(meth)acrylate and glycerol mono(meth)acrylate and optionally (b2) at least one unsaturated compound selected from the group consisting of styrene, methyl(meth)acrylate, allyl(meth)acrylate and phenyl(meth)acrylate.

The preferred carboxyl group-containing copolymer (I-1) is, for example, a copolymer (to be referred to as “carboxyl group-containing copolymer (I-2)” hereinafter) of a monomer mixture of (b1) an unsaturated compound which contains (meth)acrylic acid as an essential component and optionally mono[2-(meth)acryloyloxyethyl]succinate and (b2) at least one unsaturated compound selected from the group consisting of polystyrene macromonomer, polymethyl (meth)acrylate macromonomer, N-phenylmaleimide, N-cyclohexylmaleimide, 2-hydroxyethyl(meth)acrylate, benzyl(meth)acrylate and glycerol mono(meth)acrylate and optionally (b2) at least one unsaturated compound selected from the group consisting of styrene, methyl(meth)acrylate, allyl(meth)acrylate and phenyl(meth)acrylate.

Specific examples of the carboxyl group-containing copolymer (I-2) include a copolymer of (meth)acrylic acid and 2-hydroxyethyl(meth)acrylate, copolymer of (meth)acrylic acid, polystyrene macromonomer and benzyl (meth)acrylate, copolymer of (meth)acrylic acid, polymethyl(meth)acrylate macromonomer and benzyl(meth)acrylate, copolymer of (meth)acrylic acid, benzyl(meth)acrylate and glycerol mono(meth)acrylate, copolymer of (meth)acrylic acid, 2-hydroxyethyl(meth)acrylate and phenyl(meth)acrylate, copolymer of (meth)acrylic acid, 2-hydroxyethyl(meth)acrylate and styrene, copolymer of (meth)acrylic acid, benzyl(meth)acrylate and glycerol mono(meth)acrylate, copolymer of (meth)acrylic acid, 2-hydroxyethyl(meth)acrylate and benzyl(meth)acrylate, copolymer of (meth)acrylic acid, polystyrene macromonomer, 2-hydroxyethyl(meth)acrylate and benzyl(meth)acrylate, copolymer of (meth) acrylic acid, polymethyl(meth)acrylate macromonomer, 2-hydroxyethyl(meth)acrylate and benzyl(meth)acrylate, copolymer of (meth)acrylic acid, N-phenylmaleimide, allyl (meth)acrylate and styrene, copolymer of (meth)acrylic acid, N-phenylmaleimide, benzyl(meth)acrylate and styrene, copolymer of (meth)acrylic acid, N-cyclohexylmaleimide, allyl(meth)acrylate and styrene, copolymer of (meth)acrylic acid, N-cyclohexylmaleimide, benzyl(meth)acrylate and styrene, copolymer of (meth)acrylic acid, N-phenylmaleimide, benzyl(meth)acrylate, glycerol mono(meth)acrylate and styrene, copolymer of (meth)acrylic acid, mono[2-(meth)acryloyloxyethyl]succinate, benzyl(meth)acrylate and glycerol mono(meth)acrylate, copolymer of (meth)acrylic acid, mono[2-(meth)acryloyloxyethyl]succinate, N-phenylmaleimide, allyl(meth)acrylate and styrene, copolymer of (meth)acrylic acid, mono[2-(meth)acryloyloxyethyl]succinate, N-phenylmaleimide, benzyl(meth)acrylate and styrene, copolymer of (meth)acrylic acid, mono[2-(meth)acryloyloxyethyl]succinate, N-cyclohexylmaleimide, allyl(meth)acrylate and styrene, copolymer of (meth)acrylic acid, mono[2-(meth)acryloyloxyethyl]succinate, N-cyclohexylmaleimide, benzyl(meth)acrylate and styrene, and copolymer of (meth)acrylic acid, mono[2-(meth)acryloyloxyethyl]succinate, N-phenylmaleimide, benzyl(meth)acrylate, glycerol mono(meth)acrylate and styrene.

Specific examples of the carboxyl group-containing copolymer (I-1) include a copolymer of (meth) acrylic acid, ω-carboxypolycaprolactone mono(meth)acrylate, N-phenylmaleimide, benzyl(meth)acrylate, glycerol mono(meth)acrylate and styrene, copolymer of (meth)acrylic acid, ω-carboxypolycaprolactone mono(meth)acrylate and 2-hydroxyethyl(meth)acrylate, copolymer of (meth)acrylic acid, ω-carboxypolycaprolactone mono(meth)acrylate, polystyrene macromonomer and benzyl(meth)acrylate, copolymer of (meth) acrylic acid, ω-carboxypolycaprolactone mono(meth)acrylate, polymethyl(meth)acrylate macromonomer and benzyl(meth)acrylate, copolymer of (meth) acrylic acid, ω-carboxypolycaprolactone mono(meth)acrylate, benzyl (meth)acrylate and glycerol mono(meth)acrylate, copolymer of (meth)acrylic acid, ω-carboxypolycaprolactone mono(meth)acrylate, 2-hydroxyethyl(meth)acrylate and phenyl(meth)acrylate, copolymer of (meth)acrylic acid, ω-carboxypolycaprolactone mono(meth)acrylate, 2-hydroxyethyl(meth)acrylate and styrene, copolymer of (meth)acrylic acid, ω-carboxypolycaprolactone mono(meth)acrylate, benzyl(meth)acrylate and glycerol mono(meth)acrylate, copolymer of (meth)acrylic acid, ω-carboxypolycaprolactone mono(meth)acrylate, 2-hydroxyethyl(meth)acrylate and benzyl(meth)acrylate, copolymer of (meth) acrylic acid, ω-carboxypolycaprolactone mono(meth)acrylate, polystyrene macromonomer, 2-hydroxyethyl(meth)acrylate and benzyl(meth)acrylate, copolymer of (meth) acrylic acid, ω-carboxypolycaprolactone mono(meth)acrylate, polymethyl(meth)acrylate macromonomer, 2-hydroxyethyl(meth)acrylate and benzyl(meth)acrylate, copolymer of (meth) acrylic acid, o-carboxypolycaprolactone mono(meth)acrylate, N-phenylmaleimide, allyl (meth)acrylate and styrene, copolymer of (meth) acrylic acid, ω-carboxypolycaprolactone mono(meth)acrylate, N-phenylmaleimide, benzyl(meth)acrylate and styrene, copolymer of (meth) acrylic acid, w-carboxypolycaprolactone mono(meth)acrylate, N-cyclohexylmaleimide, allyl (meth)acrylate and styrene, copolymer of (meth) acrylic acid, ω-carboxypolycaprolactone mono(meth)acrylate, N-cyclohexylmaleimide, benzyl(meth)acrylate and styrene, copolymer of (meth) acrylic acid, ω-carboxypolycaprolactone mono(meth)acrylate, N-phenylmaleimide, benzyl (meth)acrylate, glycerol mono(meth)acrylate and styrene, copolymer of (meth)acrylic acid, ω-carboxypolycaprolactone mono(meth)acrylate, mono[2-(meth)acryloyloxyethyl]succinate, benzyl(meth)acrylate and glycerol mono(meth)acrylate, copolymer of (meth)acrylic acid, o-carboxypolycaprolactone mono(meth)acrylate, mono[2-(meth)acryloyloxyethyl]succinate, N-phenylmaleimide, allyl(meth)acrylate and styrene, copolymer of (meth)acrylic acid, ω-carboxypolycaprolactone mono(meth)acrylate, mono[2-(meth)acryloyloxyethyl]succinate, N-phenylmaleimide, benzyl(meth)acrylate and styrene, copolymer of (meth) acrylic acid, ω-carboxypolycaprolactone mono(meth)acrylate, mono[2-(meth)acryloyloxyethyl]succinate, N-cyclohexylmaleimide, allyl(meth)acrylate and styrene, copolymer of (meth) acrylic acid, ω-carboxypolycaprolactone mono(meth)acrylate, mono[2-(meth)acryloyloxyethyl]succinate, N-cyclohexylmaleimide, benzyl(meth)acrylate and styrene, and copolymer of (meth)acrylic acid, ω-carboxypolycaprolactone mono(meth)acrylate, mono[2-(meth)acryloyloxyethyl]succinate, N-phenylmaleimide, benzyl(meth)acrylate, glycerol mono(meth)acrylate and styrene.

The polymerization ratio of the polymerizable unsaturated compound having an alkali-soluble functional group in the resin (B1) is preferably 1 to 100 wt %, more preferably 5 to 30 wt %, particularly preferably 10 to 30 wt % based on the total of all the unsaturated compounds. When the polymerization ratio of the polymerizable unsaturated compound having an alkali-soluble functional group is lower than 1 wt %, the solubility in an alkali developer of the obtained resin may lower.

The copolymerization ratio of the polymerizable unsaturated compound having an alkali-soluble functional group in the alkali-soluble copolymer is preferably 1 to 40 wt %, more preferably 5 to 30 wt %, particularly preferably 10 to 30 wt % based on the total of all the unsaturated compounds. When the copolymerization ratio of the polymerizable unsaturated compound having an alkali-soluble functional group is lower than 1 wt %, the solubility in an alkali developer of the obtained alkali-soluble copolymer may lower and when the copolymerization ratio is higher than 40 wt %, the solubility in an alkali developer of the obtained alkali-soluble copolymer becomes too high, whereby the pattern shape may be impaired.

A description is subsequently given of polymerization for the manufacture of the resin (B1).

The resin (B1) can be manufactured by the polymerization of polymerizable unsaturated compounds constituting the resin (B1) in a solvent in the presence of a radical polymerization initiator and a disulfide compound (1). Thereby, the group represented by the above formula (i) or (ii) is introduced into at least one terminal of the formed polymer chain.

The polymerization of the polymerizable unsaturated compounds in the presence of the disulfide compound (1) may be living radical polymerization having an active radical at the growth terminal of the polymer chain.

In the case of living radical polymerization, when a compound having a functional group which may deactivate an active radical such as a carboxyl group is used as the polymerizable unsaturated compound, the resin (B1) can be also obtained by deprotecting the functional group contained in the polymerizable unsaturated compound after polymerization is carried out by protecting the functional group by esterification as required so as to prevent the deactivation of the living radical at the growth terminal.

The above radical polymerization initiator is suitably selected according to the types of the polymerizable unsaturated compounds in use, and generally known radical polymerization initiators may be used, as exemplified by azo compounds, organic peroxides, hydrogen peroxide, and redox-based initiators composed of these peroxides and reducing agents.

The azo compounds include azobisisobutyronitrile (AIBN), 2,2′-azobis(isobutyronitrile), 2,2′-azobis(2,4-dimethylvaleronitrile), 2,2′-azobis(4-methoxy-2,4-dimethylvaleronitrile), 2,2′-azobis(2-butanenitrile), 4,4′-azobis(4-pentanoic acid), 1,1′-azobis(cyclohexanecarbonitrile), 2-(t-butylazo)-2-cyanopropane, 2,2′-azobis[2-methyl-N-(1,1)-bis(hydroxymethyl)-2-hydroxyethyl]propionamide, 2,2′-azobis[2-methyl-N-hydroxyethyl)propionamide, 2,2′-azobis(N,N′-dimethyleneisobutylamidine)dichloride, 2,2′-azobis(2-amidinopropane)dichloride, 2,2′-azobis(N,N′-dimethyleneisobutylamide), 2,2′-azobis(2-methyl-N-[1,1-bis(hydroxymethyl)-2-hydroxy ethyl]propionamide), 2,2′-azobis(2-methyl-N-[1,1-bis(hydroxymethyl)ethyl]propionamide), 2,2′-azobis[2-methyl-N-(2-hydroxyethyl)propionamide] and 2,2′-azobis(isobutylamide)dehydrate.

The organic peroxides include t-butylhydroperoxide, cumene hydroperoxixe, t-butyl peroxyacetate, t-butyl peroxybenzoate, t-butyl peroxyoctanoate, t-butyl peroxyneodecanoate, t-butyl peroxyisobutyrate, lauroyl peroxide, t-amyl peroxypyvalate, t-butyl peroxypyvalate, dicumyl peroxide, benzoyl peroxide, 1,1′-bis(t-butylperoxy)cyclohexane and t-butylperoxypyvalate.

The redox-based initiators composed of peroxides and reducing agents include a mixture of hydrogen peroxide or alkyl peroxide, perester or percarbonate and iron salt, titanium salt (II), zinc formaldehyde sulfoxylate or sodium formaldehyde sulfoxylate and a reducing sugar; a combination of an alkali metal or ammonium salt of persulfuric acid, perboric acid or perchloric acid and an alkali metal salt of bisulfate such as sodium meta-bisulfate and a reducing sugar; and a combination of an alkali metal salt of persulfate, aryl phosphonic acid such as benzenephosphonic acid, another similar acid and a reducing sugar.

Out of these radical polymerization initiators, azo compounds such as 2,2′-azobisisobutyronitrile and 2,2′-azobis(2,4-dimethylvaleronitrile) are particularly preferred because a by-reaction product is hardly produced by oxygen or the like.

The above radical polymerization initiators may be used alone or in combination of two or more.

Examples of the non-substituted or substituted alkyl group having 1 to 20 carbon atoms represented by Z¹ and Z² in the formula (1) indicating the disulfide compound (I) are the same as those enumerated for the non-substituted or substituted alkyl group having 1 to 20 carbon atoms represented by Z¹ in the formula (i) and Z² in the formula (ii). Examples of the non-substituted or substituted monovalent aromatic hydrocarbon group having 6 to 20 carbon atoms represented by Z¹ and Z² are the same as those enumerated for the non-substituted or substituted monovalent aromatic hydrocarbon group having 6 to 20 carbon atoms represented by Z¹ in the above formula (i) and Z² in the above formula (ii). Examples of the non-substituted or substituted monovalent heterocyclic group having 3 to 20 atoms consisting of carbon atoms and other atoms represented by Z¹ and Z² are the same as those enumerated for the non-substituted or substituted monovalent heterocyclic group having 3 to 20 atoms consisting of carbon atoms and other atoms represented by Z¹ in the above formula (1) and Z² in the above formula (ii). Examples of —OR¹, —SR¹, —C(═O)OR¹, —N(R¹) (R²), —OC(═O)R¹, —C(═O)N(R¹)(R²), —P(═O) (OR¹)₂ and —P(═O)(R¹)₂ represented by Z¹ and Z² are the same as the respective non-substituted or substituted groups represented by Z¹ in the above formula (i) and Z² in the above formula (ii). Examples of the monovalent group having a polymer chain represented by Z¹ and Z² are the same as those enumerated for the monovalent group having a polymer chain represented by Z¹ in the above formula (i) and Z² in the above formula (ii).

In the formula (1), Z¹ and Z² are each preferably a group having the carbon atom of a thiocarbonyl group (C═S) in the formula (1) covalently bonded to a different atom such as nitrogen atom or oxygen atom in Z¹ and Z², more specifically a monovalent heterocyclic group having 3 to 20 atoms consisting of carbon atoms and other atoms, —OR¹ or —N(R¹)(R²), particularly preferably methyl group, ethyl group, 1-pyrrol group, 1-pyrazole group, methoxy group, ethoxy group, dimethylamino group or diethylamino group, from the viewpoint of reactivity with the polymerizable unsaturated compounds, besides an alkyl group having 1 to 20 carbon atoms.

In the present invention, the disulfide compounds (1) may be used alone or in combination of two or more.

Examples of the disulfide compound which is preferably used in the present invention include tetraethylthiuram disulfide and N,N′-diethyl-N,N′-diphenylthiuram disulfide.

The methods of preparing these disulfide compounds are generally disclosed by known documents. Particularly, thiuram disulfide can be obtained by reacting a corresponding amine with carbon disulfide in the presence of an alkali to obtain alkali metal salt of dithiocarbamic acid and oxidizing it with an oxidizing agent.

For the above polymerization, at least one other molecular weight control agent such as α-methylstyrene dimer or t-dodecylmercaptan may be used in combination with the disulfide compound (1).

The solvent used for the above polymerization is not particularly limited. Examples of the solvent include propylene glycol monoalkyl ethers such as propylene glycol monomethyl ether and propylene glycol monoethyl ether; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate and dipropylene glycol monoethyl ether acetate; (poly)alkylene glycol diethers such as diethylene glycol dimethyl ether, diethylene glycol methyl ethyl ether, diethylene glycol diethyl ether, dipropylene glycol dimethyl ether, dipropylene glycol methyl ethyl ether and dipropylene glycol diethyl ether; other ethers such as tetrahydrofuran; ketones such as methyl ethyl ketone, cyclohexanone, 2-heptanone and 3-heptanone; ketoalcohols such as diacetone alcohol (that is, 4-hydroxy-4-methylpentan-2-one) and 4-hydroxy-4-methylhexan-2-one; alkyl lactates such as methyl lactate and ethyl lactate; other esters such as ethyl 2-hydroxy-2-methylpropionate, ethyl hydroxyacetate, methyl 2-hydroxy-3-methylbutanoate, methyl 3-methoxypropionate, ethyl 3-methoxypropionate, methyl 3-ethoxypropionate, ethyl 3-ethoxypropionate, ethyl ethoxyacetate, 3-methyl-3-methoxybutylacetate, 3-methyl-3-methoxybutylpropionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate and ethyl 2-oxobutanoate; aromatic hydrocarbons such as toluene and xylene; and amides such as N-methylpyrrolidone, N,N-dimethylformamide and N,N-dimethylacetamide.

Out of these solvents, propylene glycol monomethyl ether, ethylene glycol monomethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, diethylene glycol dimethyl ether, diethylene glycol methyl ethyl ether, dipropylene glycol dimethyl ether, cyclohexanone, 2-heptanone, 3-heptanone, ethyl 3-methoxypropionate, methyl 3-ethoxypropionate, ethyl 3-ethoxypropionate, 3-methyl-3-methoxybutylpropionate, n-butyl acetate, i-butyl acetate, n-pentyl formate, i-pentyl acetate, n-butyl propionate, ethyl butyrate, i-propyl butyrate, n-butyl butyrate and ethyl pyruvate are preferred because the active radical is not deactivated at the time of living radical polymerization and from the viewpoints of the solubility of each component, pigment dispersibility and coatability of the radiation sensitive resin composition.

The above solvents may be used alone or in combination of two or more.

The amount of the radical polymerization initiator in the above polymerization is preferably 0.1 to 50 parts by weight, more preferably 0.1 to 20 parts by weight based on 100 parts by weight of the total of all the unsaturated compounds.

The amount of the disulfide compound (I) is preferably 0.1 to 50 parts by weight, more preferably 0.2 to 16 parts by weight, particularly preferably 0.4 to 8 parts by weight based on 100 parts by weight of the total of all the unsaturated compounds. When the amount of the disulfide compound (I) is smaller than 0.1 part by weight, the effect of limiting the molecular weight and the molecular weight distribution may lower and when the amount is larger than 50 parts by weight, a low molecular weight component may be formed first.

The amount of the other molecular weight control agent is preferably 200 parts or less by weight, more preferably 40 parts or less by weight based on 100 parts by weight of the total of all the molecular weight control agents. When the amount of the other molecular weight control agent is larger than 200 parts by weight, the desired effect of the present invention may be impaired.

The amount of the solvent is preferably 50 to 1,000 parts by weigh, more preferably 100 to 500 parts by weight based on 100 parts by weight of the total of all the unsaturated compounds.

The polymerization temperature is preferably 0 to 150° C., more preferably 50 to 120° C., and the polymerization time is preferably 10 minutes to 20 hours, more preferably 30 minutes to 6 hours.

Mw (weight average molecular weight in terms of polystyrene measured by gel permeation chromatography (GPC)) of the resin (B-1) is preferably 1,000 to 45,000, more preferably 3,000 to 20,000, particularly preferably 4,000 to 10,000.

Mw/Mn (Mn is number average molecular weight in terms of polystyrene measured by gel permeation chromatography (GPC)) of the resin (B-1) is preferably 1 to 2.0, more preferably 1 to 1.4.

A radiation sensitive resin composition having excellent developability is obtained by using a resin (B-1) having the above specific Mw, preferably further the above specific Mw/Mn, whereby pixels having a sharp pattern edge can be formed, the residue, stain or film residue is hardly produced on the substrate or light screening layer of an unexposed portion at the time of development, a high product yield can be obtained without producing dry foreign matter at the time of manufacturing a color filter due to high cleanability with an organic solvent, and the “burning” of a color filter can be effectively prevented.

The resins (B-1) may be used alone or in combination of two or more.

In the present invention, at least one alkali-soluble resin different from the resin (B-1) may be used in combination with the resin (B-1).

In the present invention, the amount of the resin (B-1) is preferably 10 to 1,000 parts by weight, more preferably 20 to 500 parts by weight based on 100 parts by weight of the colorant (A). When the amount of the resin (B-1) is smaller than 10 parts by weight, alkali developability may lower, or a stain or the film residue may be produced on the substrate or light screening layer of an unexposed portion and when the amount is larger than 1,000 parts by weight, the concentration of the pigment becomes relatively low, thereby making it difficult to achieve the target color density of a thin film.

The amount of the another alkali-soluble resin is preferably 50 wt % or less, more preferably 20 wt % or less of the total of all the alkali-soluble resins. When the amount of the another alkali-soluble resin is larger than 50 wt %, the desired effect of the present invention may be impaired.

### —(C) Polyfunctional Monomer—

The polyfunctional monomer in the present invention is a monomer having two or more polymerizable unsaturated bonds.

Examples of the polyfunctional monomer include di(meth)acrylates of an alkylene glycol such as ethylene glycol and propylene glycol; di(meth)acrylates of a polyalkylene glycol such as polyethylene glycol having a polymerization degree of 2 or more and polypropylene glycol having a polymerization degree of 2 or more; poly(meth)acrylates of a polyhydric alcohol having 3 or more hydroxyl groups and dicarboxylic acid modified products thereof such as glycerin, trimethylolpropane, pentaerythritol and dipentaerythritol; oligo(meth)acrylates such as polyester, epoxy resin, urethane resin, alkyd resin, silicone resin and spiran resin; di(meth)acrylates of a polymer having a hydroxyl group at both terminals such as poly-1,3-butadiene having a hydroxyl group at both terminals, polyisoprene having a hydroxyl group at both terminals and polycaprolactone having a hydroxyl group at both terminals; and tris[2-(meth)acryloyloxyethyl]phosphate.

Out of these polyfunctional monomers, poly(meth)acrylates of a polyhydric alcohol having 3 or more hydroxyl groups and dicarboxylic acid modified products thereof are preferred, as exemplified by trimethylolpropane tri(meth)acrylate, pentaerythritol tri(meth)acrylate, pentaerythritol tetra(meth)acrylate, dipentaerythritol penta(meth)acrylate and dipentaerythritol hexa(meth)acrylate. Out of these, trimethylolpropane triacrylate, pentaerythritol triacrylate and dipentaerythritol hexaacrylate are particularly preferred. These preferred polyfunctional monomers provide pixels having excellent strength and surface smoothness and rarely produce a stain or the film residue on the substrate or light screening layer of an unexposed portion.

The above polyfunctional monomers may be used alone or in combination of two or more.

The amount of the polyfunctional monomer in the present invention is preferably 5 to 500 parts by weight, more preferably 20 to 300 parts by weight based on 100 parts by weight of the alkali-soluble resin (B). When the amount of the polyfunctional monomer is smaller than 5 parts by weight, the strength and surface smoothness of the pixels may degrade and when the amount is larger than 500 parts by weight, alkali developability may lower, or a stain or the film residue may be produced on the substrate or light screening layer of an unexposed portion.

In the present invention, the polyfunctional monomer may be used in combination with a monofunctional monomer having one polymerizable unsaturated bond.

Examples of the above monofunctional monomer include unsaturated monomers (b1) and unsaturated monomers (b2) enumerated for the above alkali-soluble copolymer (I), N-vinyl nitrogen-containing heterocyclic compounds such as N-vinylsuccinimide, N-vinylpyrrolidone, N-vinylphthalimide, N-vinyl-2-piperidone, N-vinyl-ε-caprolactam, N-vinylpyrrole, N-vinylpyrrolidine, N-vinylimidazole, N-vinylimidazolidine, N-vinylindole, N-vinylindoline, N-vinylbenzimidazole, N-vinylcarbazole, N-vinylpiperidine, N-vinylpiperazine, N-vinylmorpholine and N-vinylphenoxazine; and N-(meth) acryloylmorpholine and commercially available M-5300, M-5400 and M-5600 (of Toagosei Chemical Industry Co., Ltd.).

These monofunctional monomers may be used alone or in combination of two or more. The amount of the monofunctional monomer is preferably 90 wt % or less, more preferably 50 wt % or less based on the total of the polyfunctional monomer and the monofunctional monomer. When the amount of the monofunctional monomer is larger than 90 wt %, the strength and surface smoothness of the pixels may degrade.

### —(D) Radiation Sensitive Radical Generator—

The radiation sensitive radical generator (to be simply referred to as “radical generator” hereinafter) in the present invention is a compound which forms a radical capable of initiating the polymerization of the above polyfunctional monomer (C) and the optionally used monofunctional monomer upon exposure to radiation such as visible radiation, ultraviolet radiation, far ultraviolet radiation, electron radiation or X-radiation.

Examples of the radical generator include an acetophenone-based compound, biimidazole-based compound, triazine-based compound, benzoin-based compound, benzophenone-based compound, α-diketone-based compound, polynuclear quinine-based compound, xanthone-based compound and diazo-based compound.

In the present invention, the radical generators may be used alone or in combination of two or more. The radical generator in the present invention is preferably at least one selected from the group consisting of acetophenone-based compound, biimidazole-based compound and triazine-based compound.

In the present invention, the amount of the radical generator is preferably 0.01 to 80 parts by weight, more preferably 1 to 60 parts by weight based on 100 parts by weight of the polyfunctional monomer (C) or the total of the polyfunctional monomer and the monofunctional monomer. When the amount of the radical generator is smaller than 0.01 part by weight, it may be difficult to obtain a color filter having a predetermined pixel pattern due to incomplete curing by exposure and when the amount is larger than 80 parts by weight, the formed pixels may fall off from the substrate during development.

Out of the preferred radical generators in the present invention, examples of the above acetophenone-based compound include 2-hydroxy-2-methyl-1-phenylpropan-1-one, 2-methyl-1-[4-(methylthio)phenyl]-2-morpholinopropanone-1,2-benzyl-2-dimethylamino-1-(4-morpholinophenyl)butanone-1,1-hydroxycyclohexyl-phenyl ketone, 2,2-dimethoxy-1,2-diphenylethan-1-one, 1,2-octanedione and 1-[4-(phenylthio)phenyl]-2-(O-benzoyloxime).

Out of these acetophenone-based compounds,
2-methyl-1-[4-(methylthio)phenyl]-2-morpholinopropanone-1,
2-benzyl-2-dimethylamino-1-(4-morpholinophenyl)butanone-1, 1,2-octanedione and
1-[4-(phenylthio)phenyl]-2-(O-benzoyloxime) are preferred.

The above acetophenone-based compounds may be used alone or in combination of two or more.

When the acetophenone-based compound is used as the radical generator, the amount of the acetophenone-based compound is preferably 0.01 to 80 parts by weight, more preferably 1 to 60 parts by weight, particularly preferably 1 to 30 parts by weight based on 100 parts by weight of the polyfunctional monomer (C) or the total of the polyfunctional monomer and the monofunctional monomer. When the amount of the acetophenone-based compound is smaller than 0.01 part by weight, it may be difficult to obtain a color filter having a predetermined pixel pattern due to incomplete curing by exposure. When the amount is larger than 80 parts by weight, the formed pixels may fall off from the substrate during development.

Examples of the above biimidazole-based compound include
2,2′-bis(2-chlorophenyl)-4,4′,5,5′-tetrakis(4-ethoxycarbonylphenyl)-1,2′-biimidazole,
2,2′-bis(2-bromophenyl)-4,4′,5,5′-tetrakis(4-ethoxycarbonylphenyl)-1,2′-biimidazole,
2,2′-bis(2-chlorophenyl)-4,4′,5,5′-tetraphenyl-1,2′-biimidazole,
2,2′-bis(2,4-dichlorophenyl)-4,4′,5,5′-tetraphenyl-1,2′-biimidazole,
2,2′-bis(2,4,6-trichlorophenyl)-4,4′,5,5′-tetraphenyl-1,2′-biimidazole,
2,2′-bis(2-bromophenyl)-4,4′,5,5′-tetraphenyl-1,2′-biimidazole,
2,2′-bis(2,4-dibromophenyl)-4,4′,5,5′-tetraphenyl-1,2′-biimidazole and
2,2′-bis(2,4,6-tribromophenyl)-4,4′,5,5′-tetraphenyl-1,2′-biimidazole.

Out of these biimidazole-based compounds,
2,2′-bis(2-chlorophenyl)-4,4′,5,5′-tetraphenyl-1,2′-biimidazole,
2,2′-bis(2,4-dichlorophenyl)-4,4′,5,5′-tetraphenyl-1,2′-biimidazole and
2,2′-bis(2,4,6-trichlorophenyl)-4,4′,5,5′-tetraphenyl-1,2′-biimidazole are preferred, and
2,2′-bis(2-chlorophenyl)-4,4′,5,5′-tetraphenyl-1,2′-biimidazole is particularly preferred.

These biimidazole-based compounds have excellent solubility in a solvent, do not form foreign matter such as an undissolved product and a precipitate, have high sensitivity, fully promote a curing reaction by exposure with a small amount of energy and do not cause a curing reaction in an unexposed portion. Therefore, the coating film obtained after exposure is clearly divided into a cured portion insoluble in a developer and an uncured portion having high solubility in a developer, thereby making it possible to form a high-definition color filter having a predetermined pixel pattern which is not undercut.

The above biimidazole-based compounds may be used alone or in combination of two or more.

When the biimidazole-based compound is used as the radical generator, the amount of the biimidazole-based compound is preferably 0.01 to 40 parts by weight, more preferably 1 to 30 parts by weight, particularly preferably 1 to 20 parts by weight based on 100 parts by weight of the polyfunctional monomer (C) or the total of the polyfunctional monomer and the monofunctional monomer. When the amount of the biimidazole-based compound is smaller than 0.01 part by weight, it may be difficult to obtain a color filter having a predetermined pixel pattern due to incomplete curing by exposure. When the amount is larger than 40 parts by weight, the formed pixels may fall off from the substrate and the film surface of the pixels may be roughened during development.

When the biimidazole-based compound is used as the radical generator in the present invention, it is preferably used in combination with the following hydrogen donor to further improve sensitivity.

The term “hydrogen donor” as used herein means a compound which can provide a hydrogen atom to a radical formed from the biimidazole-based compound upon exposure.

The hydrogen donor in the present invention is preferably a mercaptan-based compound or an amine-based compound defined hereinbelow.

The above mercaptan-based compound is a compound having a benzene ring or a hetero ring as a mother nucleus and 1 or more, preferably 1 to 3, more preferably 1 or 2 mercapto groups directly bonded to the mother nucleus (to be referred to as “mercaptan-based hydrogen donor” hereinafter).

The above amine-based compound is a compound having a benzene ring or a hetero ring as a mother nucleus and 1 or more, preferably 1 to 3, more preferably 1 or 2 amino groups directly bonded to the mother nucleus (to be referred to as “amine-based hydrogen donor” hereinafter).

These hydrogen donors may have a mercapto group and an amino group at the same time.

A detailed description is subsequently given of the hydrogen donor.

The mercaptan-based hydrogen donor may have at least one benzene ring or hetero ring, or both of them. When it has two or more of the rings, a fused ring may or may not be formed.

When the mercaptan-based hydrogen donor has two or more mercapto groups, as far as at least one free mercapto group remains, at least one of the other mercapto groups may be substituted by an alkyl, aralkyl or aryl group. Further, as far as at least one free mercapto group remains, the mercaptan-based hydrogen donor may have a structural unit in which two sulfur atoms are bonded together by a divalent organic group such as an alkylene group, or a structural unit in which two sulfur atoms are bonded together in the form of a disulfide.

Further, the mercaptan-based hydrogen donor may be substituted by a carboxyl group, alkoxycarbonyl group, substituted alkoxycarbonyl group, phenoxycarbonyl group, substituted phenoxycarbonyl group or nitrile group at a position other than the mercapto group(s).

Examples of this mercaptan-based hydrogen donor include 2-mercaptobenzothiazole, 2-mercaptobenzoxazole, 2-mercaptobenzoimidazole, 2,5-dimercapto-1,3,4-thiadiazole and 2-mercapto-2,5-dimethylaminopyridine.

Out of these mercaptan-based hydrogen donors, 2-mercaptobenzothiazole and 2-mercaptobenzoxazole are preferred, and 2-mercaptobenzothiazole is particularly preferred.

The amine-based hydrogen donor may have at least one benzene ring or hetero ring, or both of them. When it has two or more of the rings, a fused ring may or may not be formed.

At least one amino group of the amine-based hydrogen donor may be substituted by an alkyl group or substituted alkyl group. The amine-based hydrogen donor may be substituted by a carboxyl group, alkoxycarbonyl group, substituted alkoxycarbonyl group, phenoxycarbonyl group, substituted phenoxycarbonyl group or nitrile group at a position other than the amino group(s).

Examples of the above amine-based hydrogen donor include 4,4′-bis(dimethylamino)benzophenone, 4,4′-bis(diethylamino)benzophenone, 4-diethylaminoacetophenone, 4-dimethylaminopropiophenone, ethyl-4-dimethylaminobenzoate, 4-dimethylaminobenzoic acid and 4-dimethylaminobenzonitrile.

Out of these amine-based hydrogen donors, 4,4′-bis(dimethylamino)benzophenone and 4,4′-bis(diethylamino)benzophenone are preferred, and 4,4′-bis(diethylamino)benzophenone is particularly preferred. The amine-based hydrogen donors serve as a sensitizer even when a radical generator other than the biimidazole-based compound is used.

In the present invention, the above hydrogen donors may be used alone or in combination of two or more. A combination of at least one mercaptan-based hydrogen donor and at least one amine-based hydrogen donor is preferably used because the formed pixels hardly fall off from the substrate during development and have high strength and sensitivity.

Preferred examples of the combination of the mercaptan-based hydrogen donor and the amine-based hydrogen donor include a combination of 2-mercaptobenzothiazole and 4,4′-bis(dimethylamino)benzophenone, combination of 2-mercaptobenzothiazole and 4,4′-bis(diethylamino)benzophenone, combination of 2-mercaptobenzoxazole and 4,4′-bis(dimethylamino)benzophenone, and combination of 2-mercaptobenzoxazole and 4,4′-bis(diethylamino)benzophenone. A combination of 2-mercaptobenzothiazole and 4,4′-bis(diethylamino)benzophenone and a combination of 2-mercaptobenzoxazole and 4,4′-bis(diethylamino)benzophenone are more preferred, and a combination of 2-mercaptobenzothiazole and 4,4′-bis(diethylamino)benzophenone is particularly preferred.

The weight ratio of the mercaptan-based hydrogen donor to the amine-based hydrogen donor in the combination of the mercaptan-based hydrogen donor and the amine-based hydrogen donor is preferably 1:1 to 1:4, more preferably 1:1 to 1:3.

When the hydrogen donor is used in combination with the biimidazole-based compound, the amount of the hydrogen donor is more preferably 0.01 to 40 parts by weight, more preferably 1 to 30 parts by weight, particularly preferably 1 to 20 parts by weight based on 100 parts by weight of the polyfunctional monomer (C) or the total of the polyfunctional monomer and the monofunctional monomer. When the amount of the hydrogen donor is smaller than 0.01 part by weight, the effect of improving sensitivity may lower and when the amount is larger than 40 parts by weight, the formed pixels may fall off from the substrate during development.

Examples of the above triazine-based compound include triazine-based compounds having a halomethyl group such as
2,4,6-tris(trichloromethyl)-s-triazine,
2-methyl-4,6-bis(trichloromethyl)-s-triazine,
2-[2-(5-methylfuran-2-yl)ethenyl]-4,6-bis(trichloromethyl)-s-triazine,
2-[2-(furan-2-yl)ethenyl]-4,6-bis(trichloromethyl)-s-triazine,
2-[2-(4-diethylamino-2-methylphenyl)ethenyl]-4,6-bis(trichloromethyl)-s-triazine,
2-[2-(3,4-dimethoxyphenyl)ethenyl]-4,6-bis(trichloromethyl)-s-triazine,
2-(4-methoxyphenyl)-4,6-bis(trichloromethyl)-s-triazine,
2-(4-ethoxystyryl)-4,6-bis(trichloromethyl)-s-triazine and
2-(4-n-butoxyphenyl)-4,6-bis(trichloromethyl)-s-triazine.

Out of these triazine-based compounds, 2-[2-(3,4-dimethoxyphenyl)ethenyl]-4,6-bis(trichloromethyl)-s-triazine is particularly preferred.

The above triazine-based compounds may be used alone or in combination of two or more.

When the triazine-based compound is used as the radical generator, the amount of the triazine-based compound is preferably 0.01 to 40 parts by weight, more preferably 1 to 30 parts by weight, particularly preferably 1 to 20 parts by weight based on 100 parts by weight of the polyfunctional monomer (C) or the total of the polyfunctional monomer and the monofunctional monomer. When the amount of the triazine-based compound is smaller than 0.01 part by weight, it may be difficult to obtain a color filter having a predetermined pixel pattern due to incomplete curing by exposure. When the amount is larger than 40 parts by weight, the formed pixels may fall off from the substrate during development.

### —Other Additives—

The radiation sensitive resin composition of the present invention contains the above components (A) to (D) as essential components and optionally other additives.

The other additives include a filler such as glass or alumina; polymer compound such as polyvinyl alcohol or poly(fluoroalkylacrylate); nonionic, cationic or anionic surfactant; adhesion accelerator such as vinyl trimethoxysilane, vinyl triethoxysilane, vinyl tri(2-methoxyethoxy)silane, N-(2-aminoethyl)-3-aminopropyl-methyl dimethoxysilane, N-(2-aminoethyl)-3-aminopropyltrimethoxysilane, 3-aminopropyltriethoxysilane, 3-glycidoxypropyltrimethoxysilane, 3-glycidoxypropyl methyl-dimethoxysilane, 2-(3,4-epoxycyclohexyl)ethyltrimethoxysilane, 3-chloropropyl methyl dimethoxysilane, 3-chloropropyltrimethoxysilane, 3-methacryloyloxypropyltrimethoxysilane or 3-mercaptopropyltrimethoxysilane; antioxidant such as 2,2-thiobis(4-methyl-6-t-butylphenol) or 2,6-di-t-butylphenol; ultraviolet light absorber such as 2-(3-t-butyl-5-methyl-2-hydroxyphenyl)-5-chlorobenzotriazole or alkoxybenzophenone; and cohesion inhibitor such as sodium polyacrylate.

### Preparation of Liquid Composition

The radiation sensitive resin composition of the present invention is generally mixed with a solvent to be prepared as a liquid composition.

A suitable solvent may be selected and used as long as it disperses or dissolves the components (A) to (D) and other additives constituting the radiation sensitive composition, does not react with these components and has suitable volatility.

Examples of the solvent include propylene glycol monoalkyl ethers such as propylene glycol monomethyl ether and propylene glycol monoethyl ether; (poly) alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate and dipropylene glycol monoethyl ether acetate; (poly)alkylene glycol diethers such as diethylene glycol dimethyl ether, diethylene glycol methyl ethyl ether, diethylene glycol diethyl ether, dipropylene glycol dimethyl ether, dipropylene glycol methyl ethyl ether and dipropylene glycol diethyl ether; other ethers such as tetrahydrofuran; ketones such as methyl ethyl ketone, cyclohexanone, 2-heptanone and 3-heptanone; ketoalcohols such as diacetone alcohol (that is, 4-hydroxy-4-methylpentan-2-one) and 4-hydroxy-4-methylhexan-2-one; alkyl lactates such as methyl lactate and ethyl lactate; other esters such as ethyl 2-hydroxy-2-methylpropionate, ethyl hydroxyacetate, methyl 2-hydroxy-3-methylbutanoate, methyl 3-methoxypropionate, ethyl 3-methoxypropionate, methyl 3-ethoxypropionate, ethyl 3-ethoxypropionate, ethyl ethoxyacetate, 3-methyl-3-methoxybutylacetate, 3-methyl-3-methoxybutylpropionate, ethyl acetate, n-propyl acetate, i-propylacetate, n-butylacetate, i-butylacetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate and ethyl 2-oxobutanoate; aromatic hydrocarbons such as toluene and xylene; and amides such as N-methylpyrrolidone, N,N-dimethylformamide and N,N-dimethylacetamide.

Out of these solvents, propylene glycol monomethyl ether, ethylene glycol monomethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, diethylene glycol dimethyl ether, diethylene glycol methyl ethyl ether, dipropylene glycol dimethyl ether, cyclohexanone, 2-heptanone, 3-heptanone, ethyl 3-methoxypropionate, methyl 3-ethoxypropionate, ethyl 3-ethoxypropionate, 3-methyl-3-methoxybutylpropionate, n-butyl acetate, i-butyl acetate, n-pentyl formate, i-pentyl acetate, n-butyl propionate, ethyl butyrate, i-propyl butyrate, n-butyl butyrate and ethyl pyruvate are particularly preferred from the viewpoints of solubility, pigment dispersibility and coatability.

The above solvents may be used alone or in combination of two or more.

Further, a high-boiling solvent such as benzyl ethyl ether, di-n-hexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate or ethylene glycol monophenyl ether acetate may be used in conjunction with the above solvent.

These high-boiling solvents may be used alone or in combination of two or more.

The amount of the solvent is not particularly limited but desirably a value which ensures that the total amount of all the components excluding the solvent of the liquid composition becomes preferably 5 to 50 wt %, particularly preferably 10 to 40 wt % from the viewpoints of the coatability and stability of the obtained liquid composition.

### Color Filter Forming Method

A description is subsequently given of the method of forming the color filter of the present invention from the radiation sensitive resin composition of the present invention.

The method of forming the color filter comprises at least the following steps (1) to (4):
(1) forming a coating film of the radiation sensitive resin composition for color filters of the present invention on a substrate;
(2) exposing at least part of the coating film to radiation;
(3) developing the coating film after exposure; and
(4) heating the coating film after development (to be referred to as “post-baking” hereinafter).

Each of the above steps will be described hereinbelow.

### —Step (1)—

First of all, a light screening layer is optionally formed on the surface of the substrate to define a portion for the formation of pixels, and then a liquid radiation sensitive resin composition for color filters, containing, for example, a red pigment is applied to this substrate and prebaked to evaporate the solvent so as to form a coating film.

The substrate used in this step is made of glass, silicon, polycarbonate, polyester, aromatic polyamide, polyamide-imide, polyimide, polyether sulfone, ring open polymer of a cyclic olefin or hydrogenated product thereof.

The substrate may be optionally subjected to a suitable pre-treatment such as chemical treatment with a silane coupling agent, plasma treatment, ion plating, sputtering, gas-phase reaction or vacuum deposition.

As means of applying the liquid composition to the substrate, a suitable coating technique such as rotational coating (spin coating), cast coating, roll coating or slit-nozzle coating may be employed. Slit-nozzle coating is preferred because the radiation sensitive resin composition of the present invention has high solubility in a cleaning solvent even after it becomes dry.

As for prebaking conditions, the coating film is preferably prebaked at 70 to 110° C. for about 2 to 4 minutes.

The thickness of the formed coating film after the removal of the solvent is preferably 0.1 to 10 μm, more preferably 0.2 to 8.0 μm, particularly preferably 0.2 to 6.0 μm.

### —Step (2)—

Thereafter, at least part of the formed coating film is exposed to radiation. When part of the coating film is exposed, a photomask having a suitable pattern is used.

The radiation used in this step is selected from visible radiation, ultraviolet radiation, far ultraviolet radiation, electron radiation and X-radiation. Radiation having a wavelength of 190 to 450 nm is preferred.

The dose of the radiation is preferably about 10 to 10,000 J/m².

### —Step (3)—

Thereafter, the exposed coating film is developed with preferably an alkali developer to dissolve and remove an unexposed portion of the coating film so as to form a pattern.

The above alkali developer is preferably an aqueous solution of sodium carbonate, sodium hydroxide, potassium hydroxide, tetramethylammonium hydroxide, choline, 1,8-diazabicyclo-[5.4.0]-7-undecene or 1,5-diazabicyclo-[4.3.0]-5-nonene.

A suitable amount of a water-soluble organic solvent such as methanol or ethanol, or a surfactant may be added to the above alkali developer. The coating film is preferably rinsed after alkali development.

Shower development, spray development, dip (immersion) development or puddle development may be employed.

As for development conditions, the coating film is preferably developed at normal temperature for about 5 to 300 sec.

### —Step (4)—

By post-baking the developed coating film, a substrate having a predetermined pixel pattern composed of a cured product of the radiation sensitive resin composition can be obtained.

As for post-baking conditions, the coating film is preferably heated at 180 to 230° C. for about 20 to 40 minutes.

The thickness of the pixel film formed as described above is preferably 0.5 to 5.0 μm, more preferably 1.5 to 3.0 μm.

By repeating the above steps (1) to (4) using liquid radiation sensitive resin compositions containing green and blue pigments, green and blue pixel patterns are formed on the same substrate, thereby making it possible to form a colored layer having predetermined red, green and blue pixel patterns on the substrate. In the present invention, the order of forming these color pixel patterns is not limited to the above order.

### Color Filter

The color filter of the present invention is formed from the radiation sensitive resin composition for color filters of the present invention.

The color filter of the present invention is extremely useful for transmission and reflection type color liquid crystal display devices, color image pick-up devices, color sensors, etc.

### Color Liquid Crystal Display Device

The color liquid crystal display device of the present invention comprises the color filter of the present invention.

The color liquid crystal display device of the present invention may have a suitable structure. For example, it may have a structure that the color filter is formed on a substrate separate from a drive substrate having a thin film transistor (TFT) and the drive substrate and the substrate having the color filter are opposed to each other with a liquid crystal layer interposed therebetween. Alternatively, it may have a structure that a substrate manufactured by forming the color filter on the surface of a drive substrate having a thin film transistor (TFT) and a substrate having ITO (tin doped indium oxide) electrodes are opposed to each other with a liquid crystal layer interposed therebetween. The latter structure can significantly improve the numerical aperture, thereby making it possible to obtain a bright high-definition liquid crystal display device.

As described above, the radiation sensitive resin composition of the present invention can provide a color filter free from “burning” at a high yield, has excellent solubility in a cleaning solvent even after it becomes dry and is suitable for slit-nozzle coating.

### EXAMPLES

The following examples are provided for the purpose of further illustrating the present invention but are in no way to be taken as limiting.

Mw and Mn of each of the resins obtained in the following Synthesis Examples were measured by gel permeation chromatography (GPC) based on the following specifications.

### Device: GPC-101 (of Showa Denko K.K.)

Column: GPC-KF-801, GPC-KF-802, GPC-KF-803 and GPC-KF-804 were combined.
Transfer phase: tetrahydrofuran containing 0.5 wt % of phosphoric acid

### Synthesis Example 1

10 parts by weight of 2,2′-azobisisobutyronitrile and 400 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate, 18.8 parts by weight of styrene and 10 parts by weight of α-methylstyrene dimer (molecular weight control agent) were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 20.1 wt %). This resin had an Mw of 5,000 and an Mw/Mn of 3.6. This resin was designated as resin (−1).

### Synthesis Example 2

2.5 parts by weight of 2,2′-azobisisobutyronitrile and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate, 18.8 parts by weight of styrene and 3 parts by weight of α-methylstyrene dimer (molecular weight control agent) were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 0.5 part by weight of 2,2′-azobisisobutyronitrile was added, and polymerization was further continued for 1 hour to obtain a resin solution (solid content of 33.2 wt %). This resin had an Mw of 14,000 and an Mw/Mn of 2.1. This resin was designated as resin (β-2).

### Synthesis Example 3

3 parts by weight of 2,2′-azobisisobutyronitrile, 4 parts by weight of tetraethylthiuram disulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 33.0 wt %). This resin had an Mw of 5,000 and an Mw/Mn of 1.7. This resin was designated as resin (B-1).

### Synthesis Example 4

3 parts by weight of 2,2′-azobisisobutyronitrile, 4 parts by weight of bis(pyrazol-1-yl-thiocarbonyl)disulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 32.8 wt %). This resin had an Mw of 5,200 and an Mw/Mn of 1.4. This resin was designated as resin (B-2).

### Synthesis Example 5

3 parts by weight of 2,2′-azobisisobutyronitrile, 4 parts by weight of bis-3,5-dimethylpyrazol-1-ylthiocarbonyl disulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 33.1 wt %). This resin had an Mw of 6,200 and an Mw/Mn of 1.8. This resin was designated as resin (B-3).

### Synthesis Example 6

3 parts by weight of 2,2′-azobisisobutyronitrile, 4 parts by weight of bis-3-methylpyrazol-1-ylthiocarbonyldisulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 32.7 wt %). This resin had an Mw of 5,900 and an Mw/Mn of 1.6. This resin was designated as resin (B-4).

### Synthesis Example 7

3 parts by weight of 2,2′-azobisisobutyronitrile, 4 parts by weight of bispyrrol-1-ylthiocarbonyl disulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 32.7 wt %). This resin had an Mw of 6,500 and an Mw/Mn of 1.8. This resin was designated as resin (B-5).

### Synthesis Example 8

3 parts by weight of 2,2′-azobisisobutyronitrile, 4 parts by weight of bisthiobenzoyl disulfide (molecular weight control agent) and 200 parts by weight of dipropylene glycol dimethyl ether were fed to a flask equipped with a cooling tube and a stirrer, 20 parts by weight of methacrylic acid, 31.2 parts by weight of N-phenylmaleimide, 30 parts by weight of benzyl methacrylate and 18.8 parts by weight of styrene were then fed to the flask, the inside of the flask was substituted by nitrogen, and the obtained reaction solution was heated at 80° C. while it was stirred gently to be polymerized by maintaining that temperature for 3 hours. The reaction solution was then heated at 100° C., 2 parts by weight of 2,2′-azobisisobutyronitrile was added, and polymerization was further continued for 1 hour to obtain a resin solution (solid content of 32.7 wt %). This resin had an Mw of 5,000 and an Mw/Mn of 1.5. This resin was designated as resin (B-6).

### Immersion Test

### Comparative Example 1

40 parts by weight of a mixture of C.I. Pigment Red 254 and C.I. Pigment Yellow 139 in a weight ratio of 50/50 as the pigment (A), 10 parts by weight of Disperbyk2001 as a dispersant and 100 parts by weight of ethyl 3-ethoxypropionate as a solvent were mixed and dispersed together by the Diamond Fine Mill (bead mill (bead diameter of 1.0 mm) of Mitsubishi Materials Corporation) for 12 hours to prepare a pigment dispersion.

100 parts of this pigment dispersion, 70 parts by weight of the resin (β-1) as the alkali-soluble resin, 80 parts by weight of dipentaerythritol hexaacrylate as the polyfunctional monomer (C), 50 parts by weight of 2-benzyl-2-dimethylamino-1-(4-morpholinophenyl)butanone-1 as the radical generator (D) and 1,000 parts by weight of propylene glycol monomethyl ether acetate as a solvent were mixed together to prepare a liquid composition (r-1).

Thereafter, the liquid composition (r-1) was applied to a 4 inch-diameter soda glass substrate having an SiO₂ film for preventing the elution of sodium ions on the surface with a spin coater and left in a clean room at 23° C. for 12 hours to be dried so as to form a coating film.

When this substrate was immersed in 100 cc of propylene glycol monomethyl ether acetate for 2 minutes, the coating film dissolved completely.

### Comparative Example 2

A liquid composition (r-2) was prepared in the same manner as in Comparative Example 1 except that 70 parts by weight of the resin (β-2) was used in place of the resin (β-1) to form a coating film on a soda glass substrate.

When this substrate was immersed in 100 cc of propylene glycol monomethyl ether acetate for 2 minutes, the coating film did not dissolve completely and a large amount of foreign matter was seen in the liquid.

### Example 1

A liquid composition (R-1) was prepared in the same manner as in Comparative Example 1 except that 70 parts by weight of the resin (B-1) was used in place of the resin (β-1) to form a coating film on a soda glass substrate.

When this substrate was immersed in 100 cc of propylene glycol monomethyl ether acetate for 2 minutes, the coating film dissolved completely.

### Example 2

A liquid composition (R-2) was prepared in the same manner as in Comparative Example 1 except that 70 parts by weight of the resin (B-2) was used in place of the resin (β-1) to form a coating film on a soda glass substrate.

When this substrate was immersed in 100 cc of propylene glycol monomethyl ether acetate for 2 minutes, the coating film dissolved completely.

### Example 3

A liquid composition (R-3) was prepared in the same manner as in Comparative Example 1 except that 70 parts by weight of the resin (B-3) was used in place of the resin (β-1) to form a coating film on a soda glass substrate.

When this substrate was immersed in 100 cc of propylene glycol monomethyl ether acetate for 2 minutes, the coating film dissolved completely.

### Example 4

A liquid composition (R-4) was prepared in the same manner as in Comparative Example 1 except that 70 parts by weight of the resin (B-4) was used in place of the resin (β-1) to form a coating film on a soda glass substrate.

When this substrate was immersed in 100 cc of propylene glycol monomethyl ether acetate for 2 minutes, the coating film dissolved completely.

### Example 5

A liquid composition (R-5) was prepared in the same manner as in Comparative Example 1 except that 70 parts by weight of the resin (B-5) was used in place of the resin (β-1) to form a coating film on a soda glass substrate.

When this substrate was immersed in 100 cc of propylene glycol monomethyl ether acetate for 2 minutes, the coating film dissolved completely.

### Example 6

A liquid composition (R-6) was prepared in the same manner as in Comparative Example 1 except that 70 parts by weight of the resin (B-6) was used in place of the resin (β-1) to form a coating film on a soda glass substrate.

When this substrate was immersed in 100 cc of propylene glycol monomethyl ether acetate for 2 minutes, the coating film dissolved completely.

### Evaluation of Coatability

### Comparative Example 3

The liquid composition (r-1) prepared in Comparative Example 1 was applied to a soda glass substrate having an SiO₂ film for preventing the elution of sodium ions on the surface by using the TR63210S-CL slit nozzle type application device for color filters (trade name) of Tokyo Ohka Kogyo Co., Ltd. and left at normal temperature for 1 hour to be dried so as to form a coating film.

When the liquid composition (r-1) was applied to a new soda glass substrate with TR63210S-CL after the slit nozzle was cleaned with a jet of propylene glycol monomethyl ether acetate, it could be applied without producing foreign matter on the formed coating film.

### Comparative Example 4

When a coatability test was carried out in the same manner as in Comparative Example 3 except that the liquid composition (r-2) prepared in Comparative Example 2 was used in place of the liquid composition (r-1), foreign matter was produced on the formed coating film and therefore, a satisfactory coating film could not be formed.

### Example 7

When a coatability test was carried out in the same manner as in Comparative Example 3 except that the liquid composition (R-1) prepared in Example 1 was used in place of the liquid composition (r-1), the liquid composition could be applied without producing foreign matter on the formed coating film.

### Example 8

When a coatability test was carried out in the same manner as in Comparative Example 3 except that the liquid composition (R-2) prepared in Example 2 was used in place of the liquid composition (r-1), the liquid composition could be applied without producing foreign matter on the formed coating film.

### Example 9

When a coatability test was carried out in the same manner as in Comparative Example 3 except that the liquid composition (R-3) prepared in Example 3 was used in place of the liquid composition (r-1), the liquid composition could be applied without producing foreign matter on the formed coating film.

### Example 10

When a coatability test was carried out in the same manner as in Comparative Example 3 except that the liquid composition (R-4) prepared in Example 4 was used in place of the liquid composition (r-1), the liquid composition could be applied without producing foreign matter on the formed coating film.

### Example 11

When a coatability test was carried out in the same manner as in Comparative Example 3 except that the liquid composition (R-5) prepared in Example 5 was used in place of the liquid composition (r-1), the liquid composition could be applied without producing foreign matter on the formed coating film.

### Example 12

When a coatability test was carried out in the same manner as in Comparative Example 3 except that the liquid composition (R-6) prepared in Example 6 was used in place of the liquid composition (r-1), the liquid composition could be applied without producing foreign matter on the formed coating film.

### Evaluation of Voltage Retention

### Comparative Example 5

The liquid composition (r-1) prepared in Comparative Example 1 was applied to a soda glass substrate having an SiO₂ film for preventing the elution of sodium ions and ITO (indium-tin oxide alloy) electrodes deposited in a predetermined shape on the surface with a spin coater and prebaked in a clean oven at 90° C. for 10 minutes to form a 2.0 μm-thick coating film.

Subsequently, the coating film was exposed to 5,000 J/m² of radiation having wavelengths of 365 nm, 405 nm and 436 nm with a high-pressure mercury lamp without using a photomask. This substrate was then immersed in a developer composed of a 0.04 wt % aqueous solution of potassium hydroxide at 23° C. for 1 minute to be developed, rinsed with super pure water, dried with air and further post-baked at 250° C. for 30 minutes to cure the coating film so as to form red pixels on the substrate. The film thickness of the pixel layer was 1.60 μm.

Then, the substrate having these pixels and a substrate having ITO electrodes deposited in a predetermined shape were joined together by a sealing agent containing 0.8 mm glass beads, and the MLC6608 liquid crystals (trade name) of Merk Co., Ltd. were injected into the space between these substrates to manufacture a liquid crystal cell.

The liquid crystal cell was then placed in a thermostatic chamber at 60° C. to measure its voltage retention by using the VHR-1A liquid crystal voltage retention measuring system (trade name) of Toyo Technica Co., Ltd. The application voltage was 5.5 V rectangular waves and the measurement frequency was 60 Hz. The voltage retention is a value obtained by dividing the potential difference of the liquid crystal cell 16.7 ms after the start of application by voltage applied at 0 ms. As a result, the voltage retention was 45%.

When the voltage retention of the liquid crystal cell is lower than 90%, the liquid crystal cell cannot maintain application voltage at a predetermined level for 16.7 ms, which means that the liquid crystals cannot be aligned fully. Therefore, a liquid crystal display device comprising a color filter formed from the liquid composition (r-1) has a high chance of causing “burning”.

### Comparative Example 6

A liquid crystal cell was manufactured in the same manner as in Comparative Example 5 except that the liquid composition (r-2) prepared in Comparative Example 2 was used in place of the liquid composition (r-1). When the voltage retention of the liquid crystal cell was measured, it was 92%. Therefore, a liquid crystal display device comprising a color filter formed from the liquid composition (r-2) has a low chance of causing “burning”.

### Example 13

A liquid crystal cell was manufactured in the same manner as in Comparative Example 5 except that the liquid composition (R-1) prepared in Example 1 was used in place of the liquid composition (r-1). When the voltage retention of the liquid crystal cell was measured, it was 92%. Therefore, a liquid crystal display device comprising a color filter formed from the liquid composition (R-1) has a low chance of causing “burning”.

### Example 14

A liquid crystal cell was manufactured in the same manner as in Comparative Example 5 except that the liquid composition (R-2) prepared in Example 2 was used in place of the liquid composition (r-1). When the voltage retention of the liquid crystal cell was measured, it was 91%. Therefore, a liquid crystal display device comprising a color filter formed from the liquid composition (R-2) has a low chance of causing “burning”.

### Example 15

A liquid crystal cell was manufactured in the same manner as in Comparative Example 5 except that the liquid composition (R-3) prepared in Example 3 was used in place of the liquid composition (r-1). When the voltage retention of the liquid crystal cell was measured, it was 93%. Therefore, a liquid crystal display device comprising a color filter formed from the liquid composition (R-3) has a low chance of causing “burning”.

### Example 16

A liquid crystal cell was manufactured in the same manner as in Comparative Example 5 except that the liquid composition (R-4) prepared in Example 4 was used in place of the liquid composition (r-1). When the voltage retention of the liquid crystal cell was measured, it was 94%. Therefore, a liquid crystal display device comprising a color filter formed from the liquid composition (R-4) has a low chance of causing “burning”.

### Example 17

A liquid crystal cell was manufactured in the same manner as in Comparative Example 5 except that the liquid composition (R-5) prepared in Example 5 was used in place of the liquid composition (r-1). When the voltage retention of the liquid crystal cell was measured, it was 90%. Therefore, a liquid crystal display device comprising a color filter formed from the liquid composition (R-5) has a low chance of causing “burning”.

### Example 18

A liquid crystal cell was manufactured in the same manner as in Comparative Example 5 except that the liquid composition (R-6) prepared in Example 6 was used in place of the liquid composition (r-1). When the voltage retention of the liquid crystal cell was measured, it was 92%. Therefore, a liquid crystal display device comprising a color filter formed from the liquid composition (R-6) has a low chance of causing “burning”.

All the above evaluation results are shown in Table 1. Although the radiation sensitive resin compositions comprising a red pigment were evaluated herein, the same results were obtained from radiation sensitive resin compositions comprising blue, green, yellow and black pigments.

TABLE 1

| | | | Immersion | | Voltage |
|---|---|---|---|---|---|
| Resin | Mw | Mw/Mn | test | Coatability | retention |
| β-1 | 5000 | 3.6 | ◯ | ◯ | X (45%) |
| β-2 | 14000 | 2.1 | X | X | ◯ (92%) |
| | | | (Foreign | (Foreign | |
| | | | matter | matter | |
| | | | produced) | produced) | |
| B-1 | 5000 | 1.7 | ◯ | ◯ | ◯ (92%) |
| B-2 | 5200 | 1.4 | ◯ | ◯ | ◯ (91%) |
| B-3 | 6200 | 1.8 | ◯ | ◯ | ◯ (93%) |
| B-4 | 5900 | 1.6 | ◯ | ◯ | ◯ (94%) |
| B-5 | 6500 | 1.8 | ◯ | ◯ | ◯ (90%) |
| B-6 | 5000 | 1.5 | ◯ | ◯ | ◯ (92%) |

 In the columns of immersion test, coatability and voltage retention, ◯ means satisfactory and X means unsatisfactory.

1. A radiation sensitive resin composition comprising (A) a colorant, (B) an alkali-soluble resin, (C) a polyfunctional monomer and (D) a radiation sensitive radical generator, wherein
the alkali-soluble resin (B) is a resin having a group represented by the following formula (1) or (ii) at least one terminal of its polymer chain. 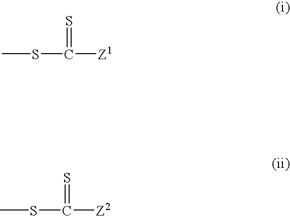
[Z¹ in the formula (i) and Z² in the formula (ii) are each independently a hydrogen atom, chlorine atom, carboxyl group, cyano group, alkyl group having 1 to 20 carbon atoms, monovalent aromatic hydrocarbon group having 6 to 20 carbon atoms, monovalent heterocyclic group having 3 to 20 atoms consisting of carbon atoms and other atoms, —OR¹, —SR¹, —OC(═O)R¹, —N(R¹) (R²), —C(═O)OR¹, —C(═O)N(R¹)(R²), —P(═O) (OR¹)₂, —P(═O)(R¹)₂ (R¹ and R² are each independently an alkyl group having 1 to 18 carbon atoms, alkenyl group having 2 to 18 carbon atoms, monovalent aromatic hydrocarbon group having 6 to 18 carbon atoms or monovalent heterocyclic group having 3 to 18 atoms consisting of carbon atoms and other atoms) or monovalent group having a polymer chain, with the proviso that the alkyl group having 1 to 20 carbon atoms, the monovalent aromatic hydrocarbon group having 6 to 20 carbon atoms, the monovalent heterocyclic group having 3 to 20 atoms consisting of carbon atoms and other atoms, R¹ and R² may be substituted.]

2. The radiation sensitive resin composition according to claim 1, wherein Z¹ and Z² are each independently a group selected from the group consisting of a monovalent heterocyclic group having 3 to 20 atoms consisting of carbon atoms and other atoms, —OR¹ and —N(R¹) (R²) (R¹ and R² are the same as R¹ and R² represented by Z¹ in the formula (i) and Z² in the formula (ii)).

3. The radiation sensitive resin composition according to claim 1 or 2, wherein the alkali-soluble resin (B) is manufactured by polymerizing polymerizable unsaturated compounds in the presence of a disulfide compound represented by the following formula (1) as a molecular weight control agent. 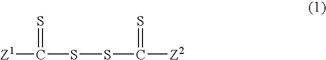
[In the formula (1), Z¹ and Z² are the same as Z¹ in the formula (i) and Z² in the formula (ii), respectively.]

4. The radiation sensitive resin composition according to claim 3, wherein polymerization for manufacturing the alkali-soluble resin (B) is living radical polymerization.

5. The radiation sensitive resin composition according to any one of claims 1 to 4, wherein the alkali-soluble resin (B) is a copolymer of a monomer mixture of (b1) an unsaturated carboxylic acid and/or an unsaturated carboxylic anhydride and (b2) another copolymerizable unsaturated compound.

6. The radiation sensitive resin composition according to any one of claims 1 to 5, wherein the weight average molecular weight Mw in terms of polystyrene measured by gel permeation chromatography (GPC) of the alkali-soluble resin (B) is 1,000 to 45,000.

7. The radiation sensitive resin composition according to any one of claims 1 to 6, wherein the ratio of Mw to the number average molecular weight Mn in terms of polystyrene measured by gel permeation chromatography of the alkali-soluble resin (B) is 1 to 2.0.

8. A method of preparing the radiation sensitive resin composition of any one of claims 1 to 7, comprising mixing a pigment dispersion obtained by mixing and dispersing a pigment as (A) a colorant in a solvent while it is ground in the presence of a dispersant with (B) an alkali-soluble resin, (C) a polyfunctional monomer and (D) a radiation sensitive radical generator.

9. The radiation sensitive resin composition according to any one of claims 1 to 7 which is used for color filters.

10. A color filter formed from the radiation sensitive resin composition of claim 9.

11. A color liquid crystal display device comprising the color filter of claim 10.
